(19) United States
(12) Patent Application Publication
(10) Pub. No.: US 2006/0148168 A1
(43) Pub. Date: Jul. 6, 2006

(54) Process for fabricating dynamic random access memory

(76) Inventors: Sheng-Chin Li, Hsinchu City (TW); Cluster Lee, Taipei City (TW)

Correspondence Address: J C PATENTS, INC., 4 VENTURE, SUITE 250, IRVINE, CA, 92618, US

(21) Appl. No.: 11/031,656

(22) Filed: Jan. 6, 2005

(51) Int. Cl. H01L 21/8242

(52) U.S. Cl. 438/239; 438/253

(57) ABSTRACT

A method of fabricating a dynamic random access memory is provided. A word line structure is formed on a substrate. A source region and a drain region are formed in the substrate on each side of the word line structure. Spacers are formed on the sidewalls of the word line structure and then a first dielectric layer having an opening for forming bit line contact and an opening for forming node contact pad is formed. A conductive layer is formed over the substrate covering the first dielectric layer and filling the bit line contact opening and the node contact pad opening. A bit line is defined and a node contact pad is formed in the node contact pad opening. A second dielectric layer having a node contact opening is formed. A node contact is formed in the node contact opening. A bottom electrode is formed on the node contact.

### BACKGROUND OF THE INVENTION

1. Field of the Invention

The present invention relates to a process for fabricating a memory device. More particularly, the present invention relates to a process for fabricating a dynamic random access memory (DRAM).

2. Description of the Related Art

With the development of powerful microprocessors, software programs of increasing size can be executed. Therefore, memories having an ever-increasing storage capacity are in great demand.

Dynamic random access memory (DRAM) utilizing capacitors as a temporary storage medium is a common type of volatile memory. According to the capacitor deployed, DRAM can be classified into two major types: namely, DRAM with a stacked capacitor and DRAM with a deep trench capacitor. However, as the dimension of devices continue to decrease, more problems are encountered in fabricating a DRAM with a stacked capacitor.

FIGS. 1A and 1B are schematic top views showing the step for fabricating a conventional dynamic random access memory. FIGS. 2A and 2B are schematic cross-sectional views along line I-I′ of FIGS. 1A and 1B. As shown in FIGS. 1A and 2A, a substrate 100 having a plurality of active regions 102 defined through a plurality of isolation structures is provided. Thereafter, a plurality of word line structures 104 is formed on the substrate 100. Each word line structure 104 comprises a gate dielectric layer 106 and a gate layer 108 sequentially stacked over the substrate 100. A source region 110a and a drain region 110b are formed in the substrate 100 on each side of the word line structure 104. After that, spacers 112 are formed on the sidewalls of the word line structures 104 and then a dielectric layer 114 is formed over the substrate 100. The dielectric layer 114 has a bit line contact opening 116 that exposes the source region 110a (the source region between two neighboring word line structure 104, or the common source region). Then, a bit line contact 118 is formed in the bit line contact opening 116. Finally, a bit line 120 having an electrical connection with the bit line contact 118 is formed over the dielectric layer 114.

As shown in FIGS. 1B and 2B, another dielectric layer 122 is formed over the substrate 100 to cover the bit line 120 and the dielectric layer 114. Thereafter, a patterned photoresist layer (not shown) is used to define a node contact opening 124 that exposes the drain region 110b. After that, a node contact 126 is formed within the node contact opening 124. Then, a lower electrode 128 is formed over the node contact 126. Hemispherical grain silicon (HSG-Si) 130 is formed over the exposed surface of the lower electrode 128 to increase the contact area between the lower electrode 130 and the capacitor dielectric layer (not shown) so that the capacitance of the capacitor is increased.

In the aforementioned fabrication process, the acceptable margin of error is reduced as the level of integration increases. Thus, misalignment in defining the contact opening is causing great problems in miniaturization. In particular, if there is some misalignment in fabricating the node contact opening 124, the subsequently formed node contact 126 may form a short circuit with the word line 104.

Furthermore, two dielectric layers 122 and 114 need to be etched in the process of defining the node contact opening 124. In other words, the node contact opening 124 has such a great deep that the process of etching the dielectric layers 122 and 114 is difficult. Therefore, the dimension of the node contact opening is frequently limited to prevent errors. That means, the node contact opening 124 has such a great deep, so the etching process cannot be performed with high etching selectivity, and one can hardly utilize the self-aligned characteristics of the spacers 112 to form the node contact opening. Under these circumstances, the size of the node contact 126 is severely limited. Consequently, the size of the subsequently formed lower electrode 130 is also severely restricted leading to a drop in the capacitance of the ultimately formed capacitor.

### SUMMARY OF THE INVENTION

Accordingly, at least one objective of the present invention is to provide a process for fabricating a dynamic random access memory (DRAM) capable of resolving misalignment problem in defining contact openings and increasing the capacitance of a capacitor constituting the DRAM.

To achieve these and other advantages and in accordance with the purpose of the invention, as embodied and broadly described herein, the invention provides a process for fabricating a dynamic random access memory. First, a word line structure is formed on a substrate. Then, a source region and a drain region are formed in the substrate on each side of the word line structure. Thereafter, spacers are formed on the sidewalls of the word line structure and then a first dielectric layer is formed over the substrate. The first dielectric layer has a bit line contact opening that exposes the source region and a node contact pad opening that exposes the drain region. After that, a conductive layer is formed over the substrate to fill the bit line contact opening and the node contact pad opening and cover the first dielectric layer. A portion of the conductive layer is removed to define a bit line over the first dielectric layer and form a node contact pad within the node contact pad opening by etching. Then, a second dielectric layer is formed over the substrate to cover the bit line. The second dielectric layer has a node contact opening that exposes the node contact pad. Thereafter, a node contact is formed within the node contact opening such that the node contact and the node contact pad are electrically connected. Finally, a lower electrode is formed over the node contact.

According to one preferred embodiment of the present invention, the method of removing a portion of the conductive layer to define a bit line over the first dielectric layer and forming a node contact pad within the node contact pad opening includes forming a patterned photoresist layer over the substrate. The patterned photoresist layer covers area for forming the bit line. Thereafter, the conductive layer not covered by the patterned photoresist layer is removed to expose the top portion of the first dielectric layer.

In the present invention, the node contact pad opening is formed before the node contact opening instead of patterning out a node contact opening in a single operation in the conventional process. In this way, misalignment during the patterning operation is greatly reduced. Furthermore, because the size of the node contact is increased, a lower electrode having a larger area can be produced to increase the capacitance of the capacitor.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are schematic top views showing the step for fabricating a conventional dynamic random access memory.

FIGS. 2A and 2B are schematic cross-sectional views along line I-I′ of FIGS. 1A and 1B.

FIGS. 3A through 3D are a series of top views showing the progression of steps for fabricating a dynamic random access memory according to one preferred embodiment of the present invention.

FIGS. 4A through 4D are a series of cross-sectional views along line II-II′ of FIGS. 3A through 3D.

FIG. 5A is a cross-sectional view along line III-III′ of FIG. 3D.

FIG. 5B is a cross-sectional view along line IV-IV′ of FIG. 3D.

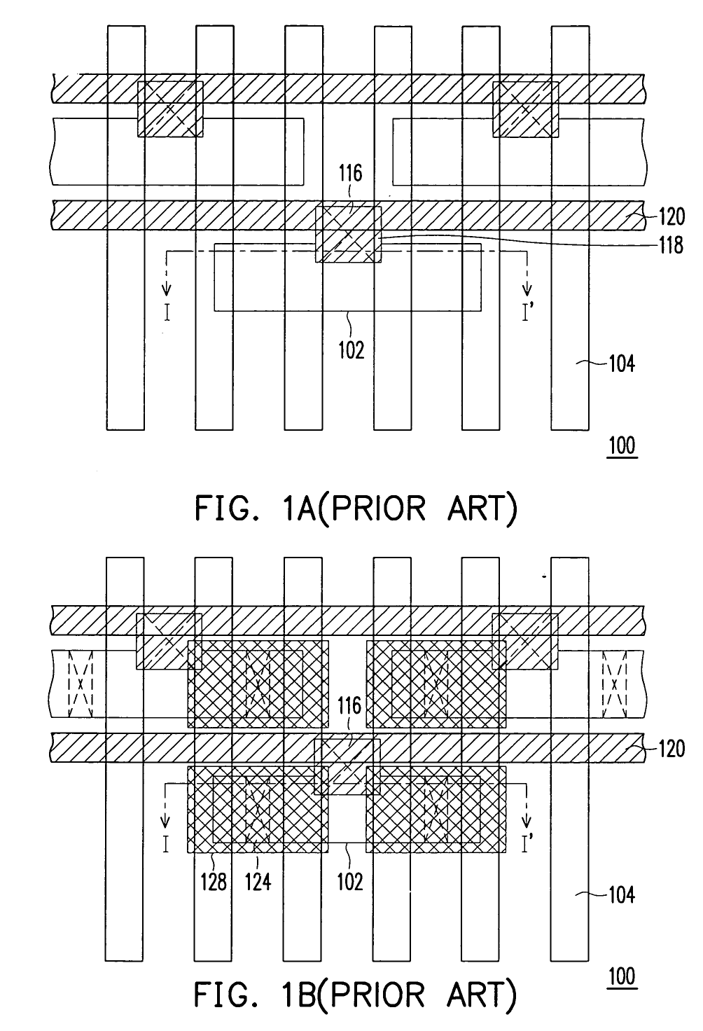

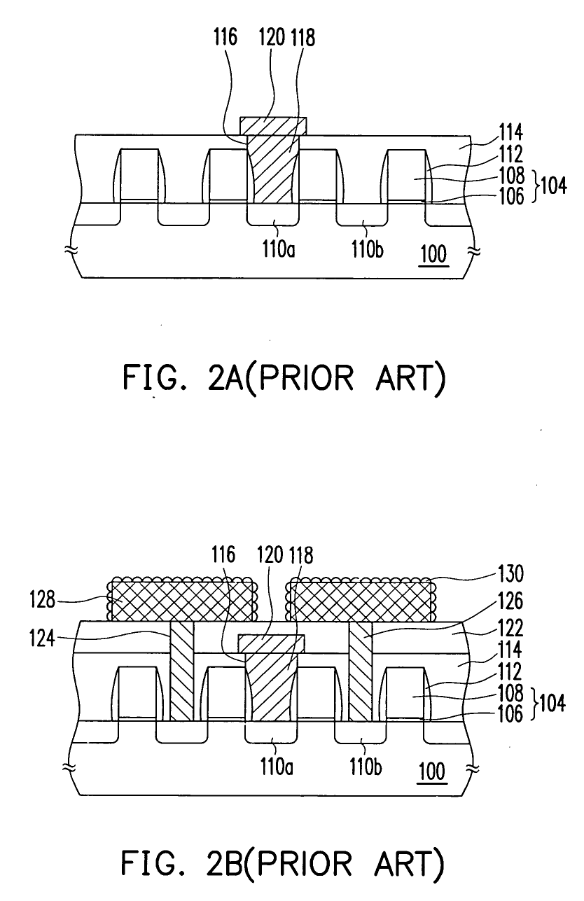

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

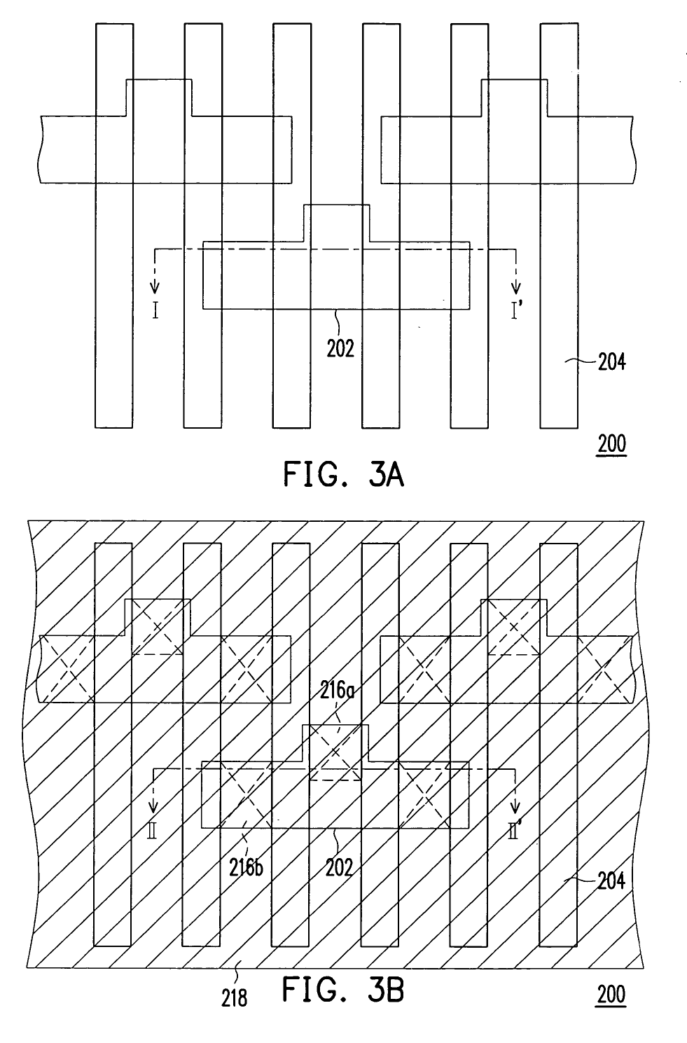

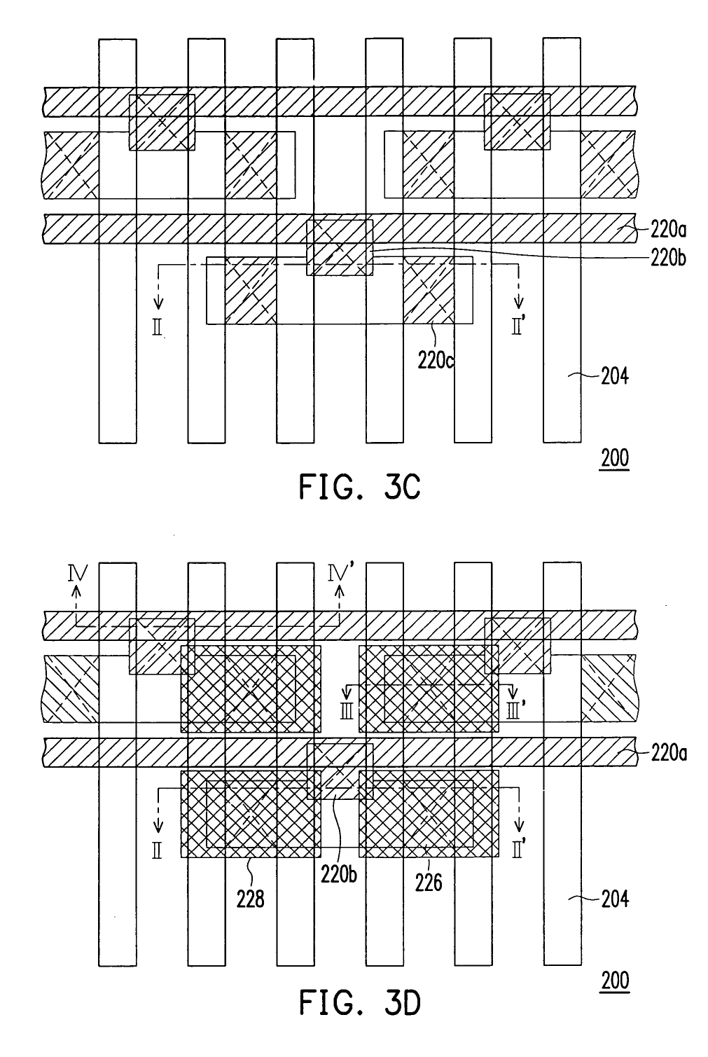

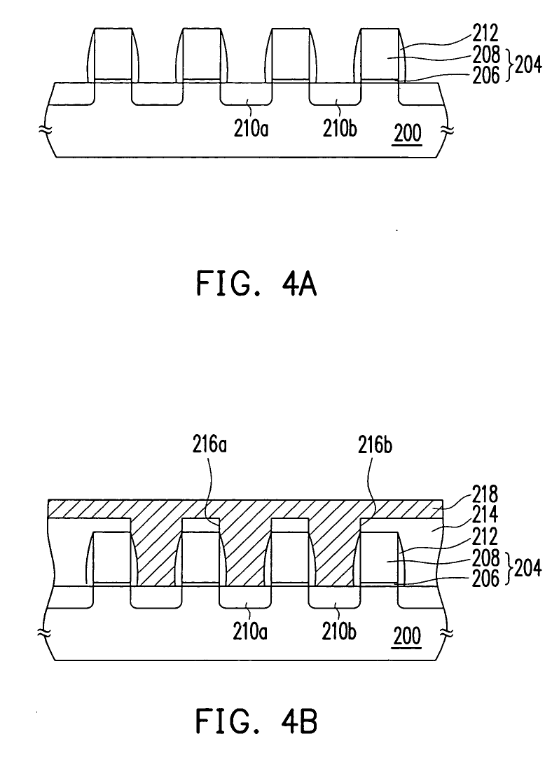

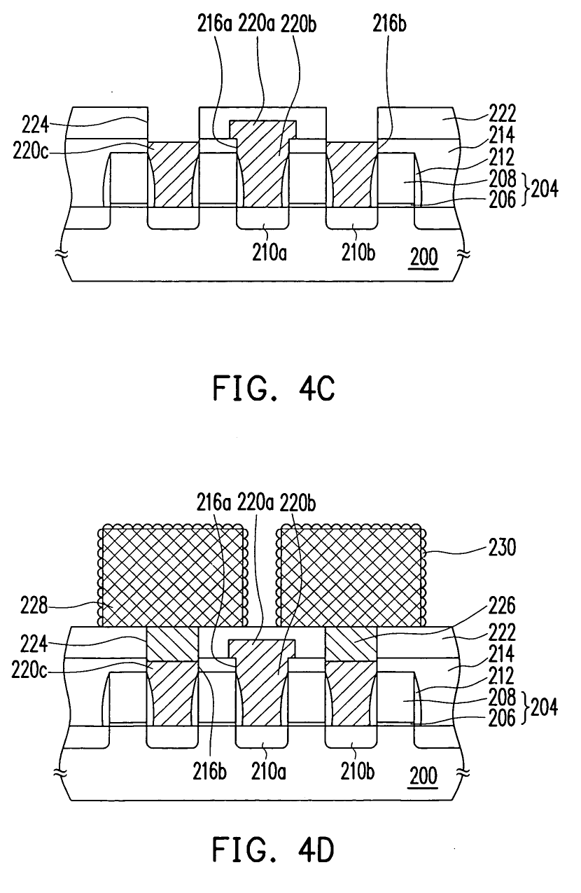

FIGS. 3A through 3D are a series of top views showing the progression of steps for fabricating a dynamic random access memory according to one preferred embodiment of the present invention. FIGS. 4A through 4D are a series of cross-sectional views along line II-II′ of FIGS. 3A through 3D. As shown in FIGS. 3A and 4A, a substrate 200 having a plurality of active regions 202 patterned out through a plurality of isolation structures is provided. Then, a plurality of word line structures 204 is formed on the substrate 200. The word line structures 204 are gate structures comprising a gate dielectric layer 206 and a gate layer 208 sequentially stacked on the substrate 200, for example.

Thereafter, a source region 210a and a drain region 210b are formed in the substrate 200 on each side of the word line structures 204. In particular, two neighboring memory cells (for example, two word line structures 204) may use a single source region 210a called the common source region. The source region 210a and the drain region 210b are formed, for example, by performing an ion implantation using the word line structures 204 as a mask.

Thereafter, spacers 212 are formed on the sidewalls of the word line structures 204. The spacers 212 are formed, for example, by forming a spacer material layer (not shown) over the substrate 200 to cover the word line structures 204 and the substrate 200 and then performing an anisotropic etching operation on the spacer material layer. The spacer material layer is fabricated using silicon nitride, for example.

As shown in FIGS. 3B and 4B, a dielectric layer 214 is formed over the substrate 200 The dielectric layer 214 has a bit line contact opening 216a that exposes the source region 210a and a node contact pad opening 216b that exposes the drain region 210b. The dielectric layer 214 is formed, for example, by depositing a dielectric material (not shown) over the substrate 200 to cover the word lines structures 204, the spacers 212 and the substrate 200. The dielectric material layer is fabricated, for example, from silicon oxide and has an etching selectivity that differs from the spacers 212. Thereafter, the dielectric material layer is patterned using a patterned photoresist layer (not shown) to form the bit line contact opening 216a that exposes the source region 210a and the node contact pad opening 216b that exposes the drain region 210b.

In particular, the node contact pad opening 216b in the present invention actually belongs to the bottom portion of the node contact opening 124 according to the prior art of fabricating the DRAM. Furthermore, because only one dielectric material layer needs to be etched, the problem related to etching out a deep opening is resolved. Moreover, due to the selectivity between the spacers and the dielectric material layer, the spacers can be utilized to form a self-aligned node contact pad opening 216b having a larger dimension.

Thereafter, a conductive layer 218 is formed over the substrate 200. The conductive layer 218 completely fills the bit line contact opening 216a and the node contact pad opening 216b and covers the dielectric layer 214. The conductive layer 218 is polysilicon layer formed, for example, by performing a chemical vapor deposition process.

As shown in FIGS. 3C and 4C, a portion of the conductive layer 218 is removed to define a bit line 220a on the dielectric layer 214 and form a bit line contact 220b inside the bit line contact opening 216a as well as a node contact pad 220c inside the node contact pad opening 216b. The bit line 220a, the bit line contact 220b and the node contact pad 220c are formed, for example, by forming a patterned photoresist layer (not shown) over the substrate 200. The patterned photoresist layer covers the area for forming the bit line. Thereafter, the conductive layer 218 not covered by the patterned photoresist layer is removed to expose the top portion of the dielectric layer 214.

Thereafter, a dielectric layer 222 is formed over the substrate 200 to cover the bit line 220a. The dielectric layer 222 has a node contact opening 224 that exposes the node contact pad 220c. The dielectric layer 222 is formed, for example, by depositing a dielectric material over the substrate 200 to form a dielectric material layer (not shown) that covers the bit line 220a and the dielectric layer 214. After that, the dielectric material layer is patterned using a patterned photoresist layer (not shown) to form the node contact opening 224 that exposes the node contact pad 220c.

In particular, the node contact pad opening 224 in the present invention actually belongs to the top portion of the node contact opening 124 according to the prior art of fabricating the DRAM. Furthermore, because the node contact pad 220c has already formed underneath the node contact opening 224, a larger processing window is available when defining the node contact opening 224. In other words, even if there is some misalignment in patterning the node contact opening 224, a short circuit between the subsequently formed node contact and the word line is easily avoided. Moreover, if a node contact opening 224 having a dimension larger than the node contact pad 220c is formed, the subsequently formed lower electrode can have a larger dimension.

As shown in FIGS. 3D and 4D, a node contact 226 is formed inside the node contact opening 224. The node contact 226 and the node contact pad 220c are electrically connected.

Thereafter, a lower electrode 228 is formed over the node contact 226. In one preferred embodiment of the present invention, the material of the lower electrode 228 may be the same with that of the node contact 226. Therefore, the node contact 226 and the lower electrode 228 are formed, for example, by depositing a conductive material such as polysilicon over the wafer 200 and filling into the node contact opening 224 to form a conductive material layer. Thereafter, a patterned photoresist layer is formed on the conductive material layer. Then, the conductive material layer will be defined as the lower electrode 228 with the patterned photoresist layer directly, for example. Since the method of the present invention is capable of forming a node contact pad 220c and a node contact 226 larger than the node contact 126 in the prior art, a thicker lower electrode can be fabricated.

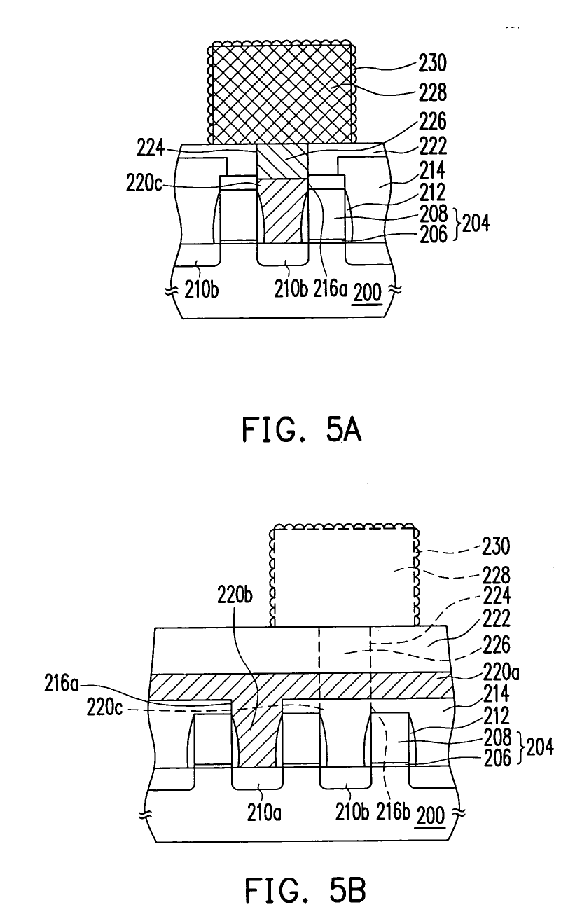

Hemispherical grain silicon (HSG-Si) 230 is formed on the surface of the lower electrode 228 to increase the contact area between the lower electrode 228 and a subsequently formed capacitor dielectric layer (not shown) so that the capacitance of the capacitor can be increased. A cross-sectional view along line III-III′ of FIG. 3D of a portion of the formed structure is shown as FIG. 5A and a cross-sectional view along line IV-IV′ of FIG. 3D of a portion of the formed structure is shown as FIG. 5B.

Because the present invention permits the formation of a thicker lower electrode 228, a larger area of the lower electrode 228 can be covered with hemispherical grain silicon (HSG-Si) 230 leading to an increase in the capacitance of the capacitor. Hence, the performance of some DRAM that demands a high capacitance such as IT-static random access memory (IT-SRAM) is significantly improved.

In summary, the node contact pad opening is formed before the node contact opening in the present invention instead of patterning out a node contact opening in a single operation as in the conventional process. In this Stay, misalignment during the patterning operation is greatly reduced. Furthermore, because the size of the node contact is increased, a lower electrode having a larger area can be produced to increase the capacitance of the capacitor.

In addition, comparing with other methods also using a node contact pad to form a node contact, the method of this invention can omit a photolithography process.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A process of fabricating dynamic random access memory (DRAM), comprising the steps of:
providing a substrate;
forming a word line structure on the substrate;
forming a source region and a drain region in the substrate on the respective sides of the word line structure;
forming spacers on the sidewalls of the word line structure;
forming a first dielectric layer over the substrate, wherein the first dielectric layer has a bit line contact opening that exposes the source region and a node contact pad opening that exposes the drain region;
forming a conductive layer over the substrate, wherein the conductive layer completely fills the bit line contact opening and the node contact pad opening and covers the first dielectric layer;
removing a portion of the conductive layer to define a bit line over the first dielectric layer and form a node contact pad inside the node contact pad opening;
forming a second dielectric layer over the substrate to cover the bit line, wherein the second dielectric layer has a node contact opening that exposes the node contact pad;
forming a node contact inside the node contact opening such that the node contact and the node contact pad are electrically connected; and
forming a lower electrode over the node contact.

2. The process of claim 1, wherein the step of removing a portion of the conductive layer to define the bit line over the first dielectric layer and forming the node contact pad inside the node contact pad opening comprises:
forming a patterned photoresist layer over the substrate, wherein the patterned photoresist layer covers the area for forming the bit line; and
removing the conductive layer not covered by the patterned photoresist layer to expose the top portion of the first dielectric layer.

3. The process of claim 1, wherein the step of forming the first dielectric layer having a bit line contact opening and a node contact pad opening thereon comprises:
forming a dielectric material layer over the substrate to cover the word line structure, the spacers and the substrate; and
removing a portion of the dielectric material layer to form a plurality of self-aligned contact openings that expose the source region and the drain region.

4. The process of claim 3, wherein the spacers and the dielectric material layer have different etching selectivity.

5. The process of claim 1, wherein the step for forming the node contact comprises:
depositing a conductive material into the node contact opening to form a conductive material layer; and
removing the conductive material layer lying outside the node contact opening.

6. The process of claim 1, wherein the step for forming the spacers comprises:
forming a spacer material layer over the substrate to cover the word line structure and the substrate; and
performing an anisotropic etching process on the spacer material layer.

7. The process of claim 1, wherein the step of forming the source region and the drain region comprises performing an ion implantation using the word line structure as a mask.

8. The process of claim 1, wherein the word line structure comprises a gate structure.

9. The process of claim 1, wherein the material constituting the conductive layer comprises polysilicon.

10. The process of claim 1, wherein the step of forming the conductive layer comprises performing a chemical vapor deposition process.

11. The process of claim 1, wherein the material of the lower electrode is the same with that of the node contact.

12. The process of claim 11, wherein the method of forming the lower electrode and the node contact comprises;
depositing a conductive material over the substrate and filling into the node contact opening to form a conductive material layer;
forming a patterned photoresist layer on the conductive material layer; and
defining the conductive material layer as the lower electrode with the patterned photoresist layer.
